(19) United States
(12) Patent Application Publication
(10) Pub. No.: US 2024/0306387 A1
(43) Pub. Date: Sep. 12, 2024

(54) MEMORY DEVICE

(71) Applicant: SK hynix Inc., Icheon-si Gyeonggi-do (KR)

(72) Inventors: Hye Yeong JUNG, Icheon-si Gyeonggi-do (KR); Jae Taek KIM, Icheon-si Gyeonggi-do (KR)

(73) Assignee: SK hynix Inc., Icheon-si Gyeonggi-do (KR)

(21) Appl. No.: 18/455,411

(22) Filed: Aug. 24, 2023

(30) Foreign Application Priority Data
Mar. 7, 2023 (KR) 10-2023-0029973

(51) Int. Cl. H10B 43/27; H10B 43/40

(52) U.S. Cl. CPC H10B 43/27; H10B 43/40

(57) ABSTRACT

A memory device, and a method of manufacturing the memory device, includes a source structure and a contact plug spaced apart from the source structure. A portion of the source structure facing the contact plug is formed to be concave.

### CROSS-REFERENCE TO RELATED APPLICATION

The present application claims priority under 35 U.S.C. § 119 (a) to Korean patent application number 10-2023-0029973 filed on Mar. 7, 2023, in the Korean Intellectual Property Office, the entire disclosure of which is incorporated by reference herein.

### BACKGROUND

### 1. Technical Field

Various embodiments of the present disclosure generally relate to a memory device and a method of manufacturing a memory device, and more particularly, to a three-dimensional memory device and a method of manufacturing a three-dimensional memory device.

### 2. Related Art

A memory device may be classified as a volatile memory device in which stored data disappears when the supply of power is interrupted or a nonvolatile memory device in which stored data is retained even when the supply of power is interrupted.

A nonvolatile memory device may include NAND flash memory, NOR flash memory, resistive random-access memory (ReRAM), phase-change random-access memory (PRAM), magnetoresistive random-access memory (MRAM), ferroelectric random-access memory (FRAM), spin transfer torque random-access memory (STT-RAM), or the like.

A memory device along with a controller configured to control the memory device may constitute a memory system. The memory device may include a memory cell array configured to store data and a peripheral circuit configured to perform a program, read, or erase operation in response to a command transmitted from the controller.

Various methods have been sought to minimize various defects occurring when manufacturing memory devices.

### SUMMARY

In an embodiment of the present disclosure, a memory device includes: a source structure including a top surface extending along a first direction and a second direction, which intersect each other, the source structure including a concave part and a protrusion part, which are alternately disposed along the first direction; a contact plug spaced apart from a sidewall of the source structure, the contact plug facing the concave part; and a gate stack structure including a plurality of insulating layers and a plurality of conductive layers, which are alternately disposed over the source structure. The protrusion part of the source structure protrudes farther in the second direction than the concave part of the source structure.

In an embodiment of the present disclosure, a memory device includes: an insulating pattern including a first part and a second part, which are alternately disposed in a first direction and are connected to each other, wherein the first part is formed with a width wider than a width of the second part in a second direction intersecting the first direction; a source structure in contact with sidewalls of the insulating pattern and extending away from the sidewalls of the insulating pattern in the second direction and in a direction opposite to the second direction, wherein the sidewalls of the insulating pattern are adjacent to each other in the second direction; a contact plug penetrating the first part of the insulating pattern; and a gate stack structure disposed over the source structure.

In an embodiment of the present disclosure, a method of manufacturing a memory device includes: forming an insulating pattern including a first part and a second part, which penetrate a preliminary source structure, the preliminary source structure including a top surface extending along a first direction and a second direction, the first part and the second part are alternately disposed in the first direction and connected to each other, wherein the first part has a width wider than a width of the second part in the second direction; forming a gate stack structure including a plurality of insulating layers and a plurality of conductive layers alternately stacked over the preliminary source structure; and forming a contact plug penetrating the first part of the insulating pattern.

### BRIEF DESCRIPTION OF THE DRAWINGS

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout the drawings.

FIG. 1 is a diagram illustrating a memory device in accordance with an embodiment of the present disclosure.

FIG. 2 is a diagram illustrating an arrangement structure of a memory cell array and a peripheral circuit, which are shown in FIG. 1.

FIG. 3 is a diagram illustrating the memory cell array shown in FIG. 2.

FIGS. 4A and 4B are views illustrating a layout of a memory device in accordance with an embodiment of the present disclosure.

FIG. 5A is a sectional view of the memory device taken along line A-A′ shown in FIGS. 4A and 4B in accordance with an embodiment of the present disclosure.

FIG. 5B is a sectional view of the memory device taken along line B-B′ shown in FIGS. 4A and 4B in accordance with an embodiment of the present disclosure.

FIGS. 6A to 6D are views illustrating a method of manufacturing a memory device in accordance with an embodiment of the present disclosure.

FIG. 7 is a diagram illustrating a Solid-State Drive (SSD) system to which the memory device of the present disclosure is applied.

FIG. 8 is a diagram illustrating a memory card system to which the memory device of the present disclosure is applied.

### DETAILED DESCRIPTION

The specific structural or functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure are directed to a memory device and a method of manufacturing a memory device, which may reduce a process defect.

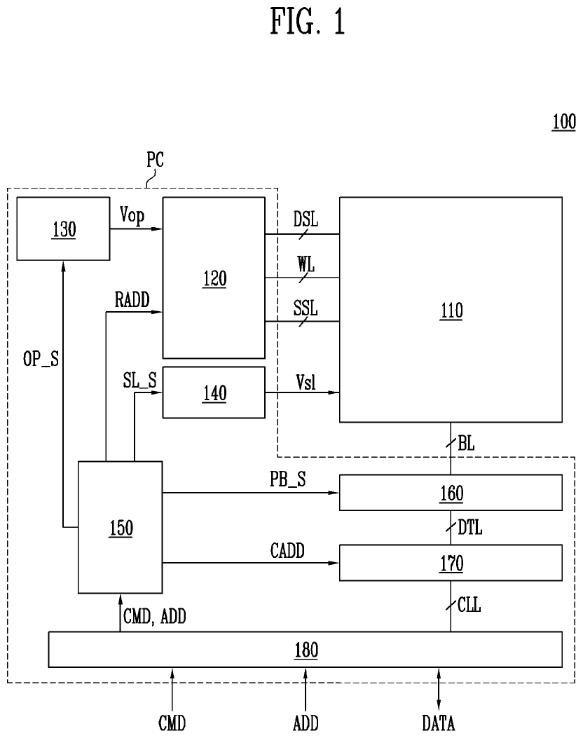

FIG. 1 is a diagram illustrating a memory device in accordance with an embodiment of the present disclosure.

Referring to FIG. 1, the memory device 100 may include a peripheral circuit PC and a memory cell array 110.

The peripheral circuit PC may be configured to perform a program operation and a verify operation, which are used to store data, to perform a read operation for outputting data stored in the memory cell array 110, or to perform an erase operation for erasing data stored in the memory cell array 110. The peripheral circuit PC may include a voltage generating circuit 130, a row decoder 120, a source line driver 140, a control circuit 150, a page buffer 160, a column decoder 170, and an input/output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of strings. Memory cells included in each of the strings may be electrically connected to each other through a channel. Channels included in the strings may be connected to the page buffer 160 through bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to the memory cell array 110 via a source structure connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit lines BL. The page buffer 160 may temporarily store data DATA received through a plurality of bit lines BL in response to the page buffer control signal PB_S. The page buffer 160 may sense a voltage or current of the plurality of bit lines BL in a read operation.

The column decoder 170 may transmit data DATA input from the input/output circuit 180 to the page buffer 160 or transmit data DATA stored in the page buffer 160 to the input/output circuit 180, in response to the column address CADD. The column decoder 170 may exchange data DATA with the input/output circuit 180 through column lines CLL, and exchange data DATA with the page buffer 160 through data lines DTL.

The input/output circuit 180 may transfer, to the control circuit 150, a command CMD and an address ADD, which are transferred from an external device (e.g., a controller) connected to the memory device 100, and output data received from the column decoder 170 to the external device.

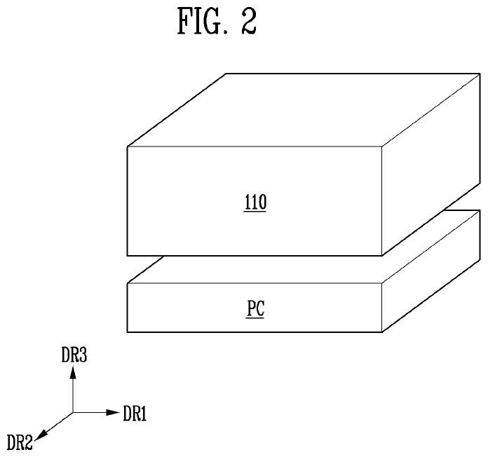

FIG. 2 is a diagram illustrating an arrangement structure of the memory cell array and the peripheral circuit, which are shown in FIG. 1.

Referring to FIG. 2, the memory cell array 110 may overlap with the peripheral circuit PC in a vertical direction. The peripheral circuit PC and the memory cell array 110 may be disposed over a first surface of a substrate, and overlap with each other in the vertical direction. The substrate may have a flat plate shape intersecting the vertical direction. For example, the first surface of the substrate may extend along an XY plane. Hereinafter, embodiments of the present disclosure will be described by defining a first direction DR1, a second direction DR2, and a third direction DR3. The first direction DR1 and the second direction DR2 may be defined as directions in which the first surface of the substrate extends. The first direction DR1 and the second direction DR2 may be defined as directions intersecting each other. The third direction DR3 may be defined as a direction intersecting the first surface of the substrate, and correspond to the above-described vertical direction.

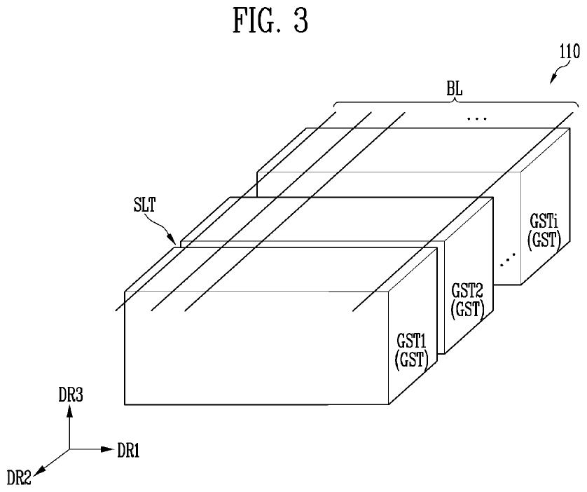

FIG. 3 is a diagram illustrating the memory cell array shown in FIG. 2.

Referring to FIG. 3, the memory cell array 110 may include a plurality of gate stack structures GST1 to GSTi (i is a positive integer). The plurality of gate stack structures GST1 to GSTi may be arranged to be spaced apart from each other along the second direction DR2.

A plurality of bit lines BL may be disposed above the plurality of gate stack structures GST1 to GSTi. The plurality of bit lines BL may be spaced apart from each other in the first direction DR1 and may extend in the second direction DR2. The plurality of bit lines BL may extend to overlap with the plurality of gate stack structures GST1 to GSTi. A source structure extending in the first direction DR1 and the second direction DR2 may be disposed under the plurality of gate stack structures GST1 to GSTi. The plurality of gate stack structures GST1 to GSTi may be partitioned by a plurality of slits SLT. Each slit SLT may be disposed between gate stack structures adjacent to each other. The plurality of slits SLT may extend in the first direction DR1, and be alternately disposed with the plurality of gate stack structures GST1 to GSTi in the second direction DR2.

Hereinafter, for convenience of description, an embodiment of the present disclosure will be described based on a gate stack structure GST disposed between slits SLT adjacent to each other.

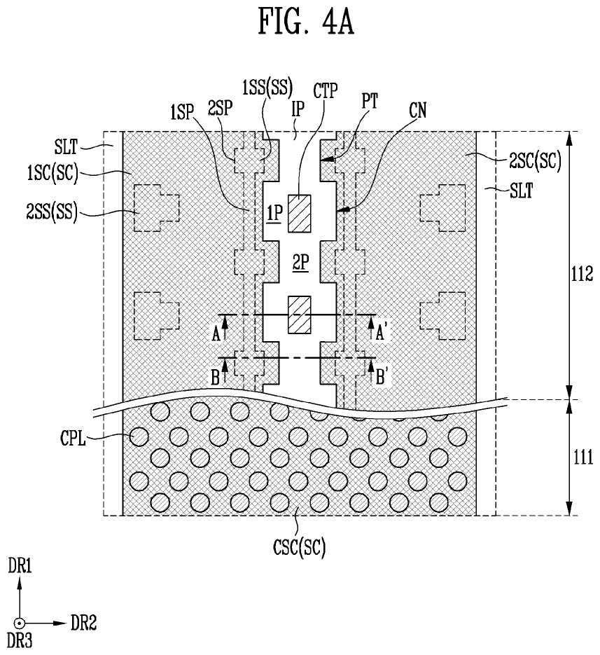

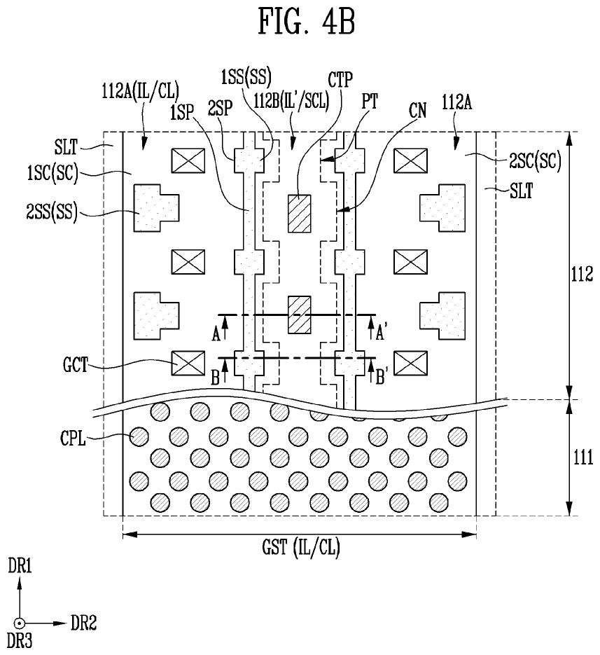

FIGS. 4A and 4B are views illustrating a layout of a memory device in accordance with an embodiment of the present disclosure.

In particular, FIG. 4A illustrates a layout of the memory device at a level at which a source structure is disposed, and FIG. 4B illustrates a layout of the memory device at a level at which a gate stack structure is disposed.

Referring to FIGS. 4A and 4B, the memory device may include a source structure SC and a gate stack structure GST. The source structure SC may include a top surface extending along the first direction DR1 and the second direction DR2, which intersect each other. The gate stack structure GST may overlap with the source structure SC in the third direction DR3 intersecting the top surface of the source structure SC. The gate stack structure GST may extend along the first direction DR1 and the second direction DR2.

The gate stack structure GST may include a cell array region 111 and a contact region 112. The contact region 112 of the gate stack structure GST may extend from the cell array region 111. In an embodiment, the contact region 112 of the gate stack structure GST may extend in the first direction DR1 from the cell array region 111. The cell array region 111 of the gate stack structure GST may include a plurality of interlayer insulating layers IL and a plurality of conductive layers CL, which are alternately disposed in the third direction DR3.

The gate stack structure GST may be partitioned by a slit SLT. In an embodiment, the gate stack structure GST may include sidewalls extending along slits SLT adjacent to each other in the second direction DR2.

A plurality of channel plugs CPL may be disposed in the cell array region 111 of the gate stack structure GST. The plurality of channel plugs CPL may extend in the third direction DR3 in the cell array region 111. The plurality of channel plugs CPL may be spaced apart from each other in the first direction DR1 and the second direction DR2. In an embodiment, a memory cell string of a NAND flash memory may be defined along each of the channel plugs CPL. To this end, each of the channel plugs CPL may include a channel layer and a memory layer surrounding a sidewall of the channel layer. The channel layer may include a semiconductor material such as germanium or silicon. The memory layer may include a blocking insulating layer, a data storage layer between the blocking insulating layer and the channel layer, and a tunnel insulating layer between the data storage layer and the channel layer. The data storage layer may include a charge trap layer, a floating gate layer, a conductive nano dot, a phase change layer, and the like. In an embodiment, the data storage layer may be configured with a charge trap layer including silicon nitride.

A plurality of channel plugs CPL may be electrically connected to a bit line (BL shown in FIG. 3) above the gate stack structure GST, and be electrically connected to the source structure SC under the gate stack structure GST. In an embodiment, a channel layer of each channel plug CPL may be electrically connected to the bit line (BL shown in FIG. 3) and the source structure SC. For an electrical connection between the channel layer of the channel plug CPL and the bit line (BL shown in FIG. 3), a conductive contact structure may be interposed between the channel layer and the bit line (BL shown in FIG. 3), or the channel layer may extend to be connected directly to the bit line (BL shown in FIG. 3). For an electrical connection between the channel layer of the channel plug CPL and the source structure SC, the channel layer may extend to the inside of the source structure SC to have a sidewall in contact with the source structure SC.

The contact region 112 of the gate stack structure GST may include first contact regions 112A adjacent to each other in the second direction DR2 and a second contact region 112B between the first contact regions 112A. The plurality of interlayer insulating layers IL and the plurality of conductive layers CL may extend from the cell array region 111 to each first contact region 112A. The second contact region 112B may include a plurality of interlayer insulating layers IL′ and a plurality of sacrificial layers SCL. A plurality of contact plugs CTP may be disposed in the second contact region 112B of the gate stack structure GST. Each of the plurality of contact plugs CTP may extend in the third direction DR3. The plurality of contact plugs CTP may be spaced apart from each other in the first direction DR1.

The source structure SC may include a first source structure 1SC, a second source structure 2SC, and a cell overlapping source structure CSC. The cell overlapping source structure CSC may overlap with the cell array region 111 of the gate stack structure GST. The first source structure 1SC and the second source structure 2SC may extend in the first direction DR1 from the cell overlapping source structure CSC. The first source structure 1SC and the second source structure 2SC may respectively overlap with the first contact regions 112A of the gate stack structure GST, which are adjacent to each other in the second direction DR2.

The plurality of contact plugs CTP may be disposed between the first source structure 1SC and the second source structure 2SC. The first source structure 1SC may be spaced apart from the second source structure 2SC. The plurality of contact plugs CTP may be spaced apart from the first source structure 1SC and the second source structure 2SC.

The source structure SC may include a sidewall extending along each of the first source structure 1SC and the second source structure 2SC. The sidewall of the source structure SC may include a plurality of concave parts CN and a plurality of protrusion parts PT, which are alternately disposed in the first direction DR1. Each protrusion part PT may protrude toward a region between the first source structure 1SC and the second source structure 2SC as compared with each concave part CN. In an embodiment, each protrusion part PT may protrude in the second direction DR2 as compared with each concave part CN. At least one of the first source structure 1SC and the second source structure 2SC may include the protrusion part PT and the concave part CN, which are described above. In an embodiment, the plurality of concave parts CN and the plurality of protrusion parts PT may be respectively disposed at sidewalls of the first source structure 1SC and the second source structure 2SC, which face each other. Each contact plug CTP may be disposed to face a concave part CN corresponding thereto. Accordingly, as compared with a case where the sidewall of the source structure SC is formed in a linear shape without any unevenness, a separation distance between the contact plug CTP and the source structure may be increased, and thus a process defect may be reduced, in which the contact plug CTP and the source structure SC are connected to each other. An increase in resistance of the source structure SC may be reduced through the protrusion part PT of the source structure SC.

The plurality of concave parts CN and the plurality of protrusion parts PT may be designed such that the sidewall of the first source structure 1SC and the sidewall of the second source structure 2SC may be spaced apart from each other at a first distance and a second distance, which are different from each other. For the first distance to be defined greater than the second distance, a concave part CN of the second source structure 2SC may face a concave part CN of the first source structure 1SC, and a protrusion part PT of the second source structure 2SC faces a protrusion part PT of the first source structure 2SC. Each contact plug CTP may be disposed between the concave part CN of the first source structure 1SC and the concave part CN of the second source structure 2SC. The contact plug CTP is disposed between the concave parts CN facing each other, so that the separation distance between the contact plug CTP and the source structure SC may be increased as compared with a case where the contact plug CTP is disposed to face only one concave part.

The first source structure 1SC and the second source structure 2SC may be spaced apart from each other in the second direction DR2 with an insulating pattern IP. The insulating pattern IP may overlap with the second contact region 112B of the gate stack structure GST. The plurality of contact plugs CTP may extend to penetrate the insulating pattern IP. Each contact plug CTP may be surrounded by the insulating pattern IP. The insulating pattern IP may include an insulating material. In an embodiment, the insulating pattern IP may include an oxide. The insulating pattern IP may be formed along the sidewalls of the first source structure 1SC and the second source structure 2SC. The first source structure 1SC and the second source structure 2SC may be in contact with sidewalls of the insulating pattern IP. The sidewalls of the insulating pattern IP are adjacent to each other in the second direction DR2. The first source structure 1SC and the second source structure 2SC may extend from the sidewalls of the insulating pattern IP in the second direction DR2 and in a direction opposite to the second direction DR2. In an embodiment, the first source structure 1SC may extend from one of the sidewalls of the insulating pattern IP in the direction opposite to the second direction DR2, and the second source structure 2SC may extend from the other of the sidewalls of the insulating pattern IP in the second direction DR2. The insulating pattern IP may include a plurality of first parts 1P and a plurality of second parts 2P, which are alternately disposed in the first direction DR1 and are connected to each other. In the insulating pattern IP, each first part 1P may have a first width in the second direction between the first source structure 1SC and the second source structure 2SC, and each second part 2P may have a second width in the second direction DR2 between the first source structure 1SC and the second source structure 2SC. The first width may be formed wider than the second width. To this end, the first part 1P of the insulating pattern IP may be disposed between the concave part CN of the first source structure 1SC and the concave part CN of the second source structure 2SC, and the second part 2P of the insulating pattern IP may be disposed between the protrusion part PT of the first source structure 1SC and the protrusion part PT of the second source structure 2SC. The plurality of concave parts CN of each of the first source structure 1SC and the second source structure 2SC may be respectively in contact with the plurality of first parts 1P of the insulating pattern IP, and the plurality of protrusion parts PT of each of the first source structure 1SC and the second source structure 2SC may be respectively in contact with the plurality of second parts 2P of the insulating pattern IP.

Each contact plug CTP may be formed to penetrate the first part 1P of the insulating pattern IP between the concave part CN of the first source structure 1SC and the concave part CN of the second source structure 2SC. Accordingly, the separation distance between the contact plug CTP and the source structure SC may be considerably formed as compared with a case where the contact plug CTP penetrates the second part 2P of the insulating pattern IP between the protrusion part PT of the first source structure 1SC and the protrusion part PT of the second source structure 2SC.

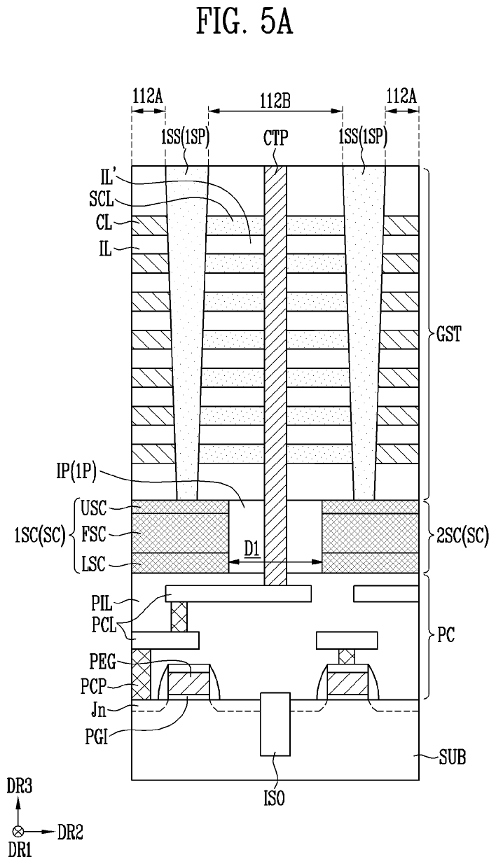

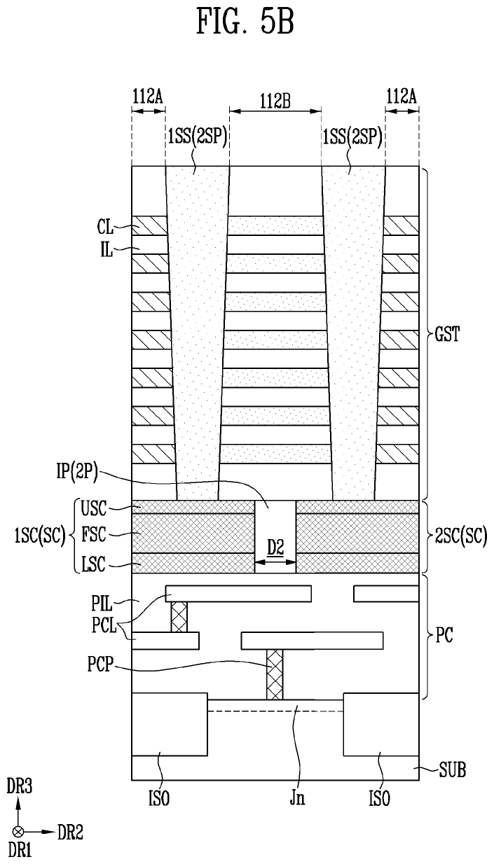

The contact plug CTP may be provided as an interconnection for transmitting a signal. In an embodiment, a peripheral circuit (PC shown in FIGS. 5A and 5B) may be disposed under the source structure SC, and the contact plug CTP may transmit a signal from the peripheral circuit (PC shown in FIGS. 5A and 5B).

In accordance with the embodiments of the present disclosure, an alignment margin of the contact plug CTP in a process of forming the contact plug CTP may be secured through the concave part CN formed at the sidewall of the source structure SC. Thus, in accordance with the embodiments of the present disclosure, a process defect may be reduced, in which the contact plug CTP is in contact with the source structure SC.

A plurality of support structures SS may be disposed in the contact region 112 of the gate stack structure GST. The plurality of support structures SS may be disposed on the source structure SC. In an embodiment, the plurality of support structures SS may include a first support structure 1SS and a second support structure 2SS, which overlap with each of the first source structure 1SC and the second source structure 2SC.

The first support structure 1SS may be disposed between each of the first contact regions 112A of the gate stack structure GST and the second contact region 112B of the gate stack structure GST. The first support structure 1SS may be formed in a line type extending along one direction. In an embodiment, the first support structure 1SS may extend in the first direction DR1. The first support structure 1SS may include a plurality of first support parts 1SP and a plurality of second support parts 2SP, which are alternately disposed in the first direction DR1. The plurality of first support parts 1SP may respectively correspond to the plurality of concave parts CN of the first source structure 1SC or the plurality of concave parts CN of the second source structure 2SC. The plurality of second support parts 2SP may respectively correspond to the plurality of protrusion parts PT of the first source structure 1SC or the plurality of protrusion parts PT of the second source structure 2SC. The plurality of second support parts 2SP may respectively correspond to the plurality of second parts 2P of the insulating pattern IP. Each of the plurality of second support parts 2SP may have a width wider than a width of each of the plurality of first support parts 1SP in the second direction DR2. Accordingly, a concave part corresponding to each first support part 1SP and a protrusion part corresponding to each second support part 2SP may be defined at a sidewall of the first support part 1SS.

The second support structure 2SS may be disposed in each first contact region 112A of the gate stack structure GST. The second support structure 2SS may be disposed between the first support structure 1SS and the slit SLT. The second support structure 2SS may be formed in various shapes. In an embodiment, the second support structure 2SS may be formed in a T-shape. The second support structure 2SS may be disposed to face the first support part 1SP of the first support structure 1SS. The second support structure 2SS may be formed in an island type. For example, a plurality of second support structures 2SS may be disposed in each contact region 112A of the gate stack structure GST to be spaced apart from each other in the first direction.

The first support structure 1SS and the second support structure 2SS may include an insulating material. In an embodiment, the first support structure 1SS and the second support structure 2SS may include an oxide.

A plurality of gate contacts GCT may be disposed in the contact region 112 of the gate stack structure GST. The plurality of gate contacts GCT may extend in the third direction DR3 while being respectively in contact with the plurality of conductive layers CL of the gate stack structure GST in each first contact region 112A of the gate stack structure GST. In an embodiment, lengths with which the plurality of gate contacts GCT extend in the third direction DR3 may be different from each other. However, the embodiment of the present disclosure is not limited thereto, and various connection structures between the plurality of gate contacts GCT and the plurality of conductive layers CL of the gate stack structure GST may be provided.

The plurality of gate contacts GCT may be disposed in various layouts. In an embodiment, each gate contact GCT may be disposed between second support structures 2SS adjacent to each other in the first direction DR1, and be disposed to face the second support part 2SP of the first support structure 1SS.

FIG. 5A is a sectional view of the memory device taken along line A-A′ shown in FIGS. 4A and 4B in accordance with an embodiment of the present disclosure.

FIG. 5B is a sectional view of the memory device taken along line B-B′ shown in FIGS. 4A and 4B in accordance with an embodiment of the present disclosure.

Referring to FIGS. 5A and 5B, a gate stack structure GST may be disposed over a source structure SC. The gate stack structure GST may include a plurality of insulating layers IL and IL′, a plurality of conductive layers CL, and a plurality of sacrificial layers SCL. The plurality of insulating layers IL and IL′ may be spaced apart from each other in the third direction DR3 in each of first and second contact regions 112A and 112B. The plurality of conductive layers CL may be alternately disposed in the third direction DR3 with a plurality of insulating layers IL in the first contact region 112A of the gate stack structure GST. The plurality of sacrificial layers SCL may be alternately disposed in the third direction DR3 with a plurality of insulating layers IL′ in the second contact region 112B of the gate stack structure GST. Although not shown in the drawings, each of the plurality of conductive layers CL may be in contact with a gate contact (GCT shown in FIG. 4B) corresponding thereto. The plurality of sacrificial layers SCL may include an insulating material having an etch selectivity with respect to the plurality of insulating layers IL and IL′. In an embodiment, each of the insulating layers IL and IL′ may include an oxide, and each of the sacrificial layers SCL may include a nitride. The plurality of sacrificial layers SCL may be respectively disposed at levels at which the plurality of conductive layers CL are disposed. The plurality of sacrificial layers SCL may be spaced apart from the plurality of conductive layers CL with a first support structure 1SS interposed therebetween.

The first support structure 1SS may be in contact with the source structure SC while penetrating the gate stack structure GST. A boundary between the first contact region 112A and the second contact region 112B of the gate stack structure GST may be defined by the first support structure 1SS. The second contact region 112B of the gate stack structure GST may extend with different widths in the second direction DR2 from a first support part 1SP and a second support part 2SP. For example, at the same level, a width of the second contact region 112B extending in the second direction DR2 from the first support part 1SP of the first support structure 1SS may be defined wider than a width of the second contact region 112B extending in the second direction DR2 from the second support part 2SP of the first support structure 1SS.

The plurality of sacrificial layers SCL and the plurality of insulating layers IL′ in the second contact region 112B of the gate stack structure GST may be penetrated by a contact plug CTP. The contact plug CTP and the first support part 1SP of the first support structure 1SS may be adjacent to each other in the second direction DR2. The contact plug CTP may extend between a first source structure 1SC and a second source structure 2SC. The contact plug CTP may penetrate a first part 1P of an insulating pattern IP disposed between the first source structure 1SC and the second source structure 2SC. The contact plug CTP may be electrically connected to a peripheral circuit PC on the bottom of the source structure SC.

The peripheral circuit PC may include peripheral gate electrodes PEG, a peripheral gate insulating layer PG1, junctions Jn, peripheral circuit lines PCL, and peripheral contact plugs PCP. The peripheral circuit PC may be covered with a peripheral circuit insulating layer PIL formed on a substrate SUB. Each of the peripheral gate electrodes PEG may be used as gate electrodes of NMOS and PMOS transistors of the peripheral circuit PC. The peripheral gate insulating layer PGI may be disposed between the peripheral gate electrode PEG and the substrate SUB. The junctions Jn may be defined by implanting an n-type or p-type impurity into an active region of the substrate SUB, and be disposed at both sides of each of the peripheral gate electrodes PEG to be used as source and drain junctions. The active region of the substrate SUB may be partitioned by an isolation layer ISO disposed in the substrate SUB. The isolation layer ISO may include an insulating material. The peripheral circuit lines PCL may be electrically connected to transistors, a resistor, a capacitor, and the like, which constitute a circuit of the peripheral circuit PC, through the peripheral contact plugs PCP. The peripheral circuit insulating layer PIL may include a multi-layer structure.

The source structure SC may be disposed between the gate stack structure GST and the peripheral circuit PC. The source structure SC may include an upper source structure USC, an interlayer source structure FSC, and a lower source structure LSC. The interlayer source structure FSC may be disposed on the top of the lower source structure LSC, and the upper source structure USC may be disposed on the top of the interlayer source structure FSC. The lower source structure LSC of the source structure SC may include a semiconductor material. In an embodiment, the semiconductor material of the lower source structure LSC may include at least one of silicon (Si), germanium (Ge), silicon germanium (SiGe), gallium arsenide (GaAs), indium gallium arsenide (InGaAs), aluminum gallium arsenide (AlGaAs), and mixtures thereof. The lower source structure LSC may have a crystalline structure including at least one of a single crystalline structure, an amorphous structure, and a polycrystalline structure. The lower source structure LSC may include at least one of an n-type impurity and a p-type impurity. In an embodiment, the lower source structure LSC may include a poly-silicon layer doped with n-type impurities. In another embodiment, the lower source structure LSC may further include a conductive material such as a metal. Each of the interlayer source structure FSC and the upper source structure USC may include various semiconductor materials exemplified as the semiconductor materials of the lower source structure LSC. Each of the interlayer source structure FSC and the upper source structure USC may include at least one of an n-type impurity and a p-type impurity. In an embodiment, each of the interlayer source structure FSC and the upper source structure USC may include a poly-silicon layer doped with an n-type impurity.

Although not shown in the drawings, the upper source structure USC and the interlayer source structure FSC may be penetrated by the channel plug CPL shown in FIGS. 4A and 4B, and the interlayer source structure FSC may be formed to be in direct contact with the channel layer of the channel plug CPL shown in FIGS. 4A and 4B. The insulating pattern IP may be disposed between the gate stack structure GST and the peripheral circuit PC. The first source structure 1SC and the second source structure 2SC in the source structure SC may be spaced apart from each other at different distances for each part with the insulating pattern IP interposed therebetween. A width of the first part IP of the insulating pattern IP may be defined as a first width D1, and a width of the second part P2 of the insulating pattern IP may be defined as a second width D2. The first width D1 of the first part P1 of the insulating pattern IP may be wider than the second width D2 of the second part P2 of the insulating pattern IP. The contact plug CTP which are to be disposed not to be in contact with the source structure SC may be connected to the peripheral circuit PC while penetrating the first part 1P of the insulating pattern IP, which is formed with a relatively wide width. Accordingly, a leakage current between the source structure SC and the contact plug PCT may be reduced.

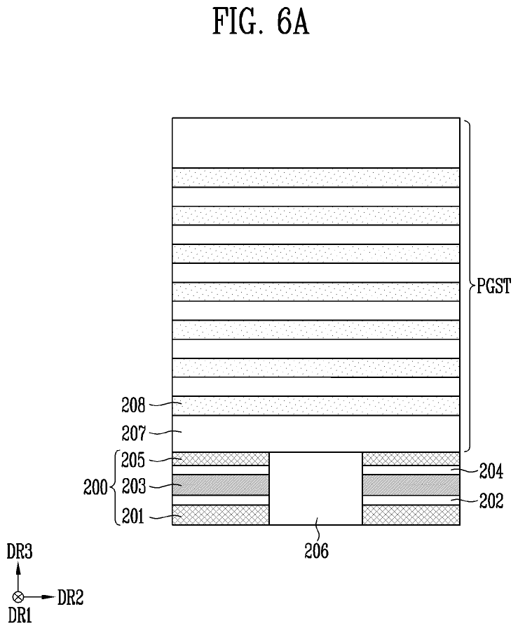

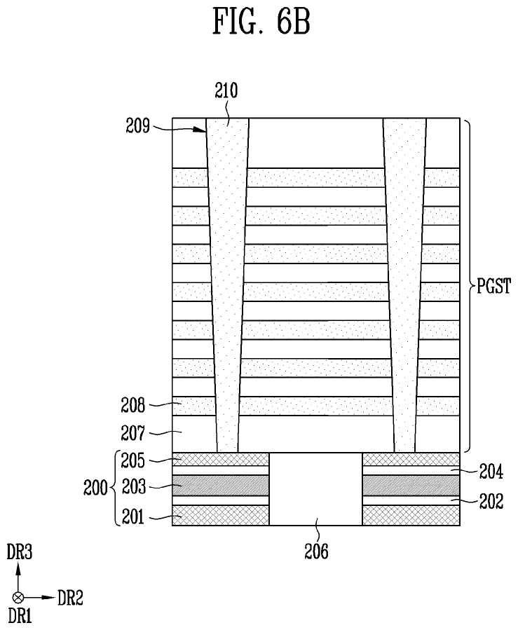

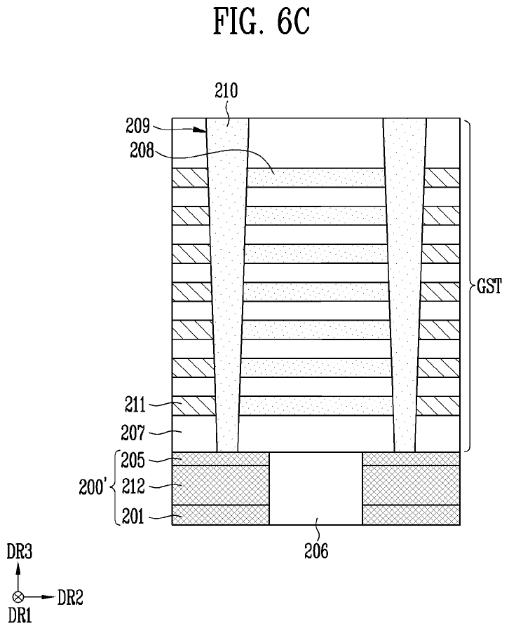

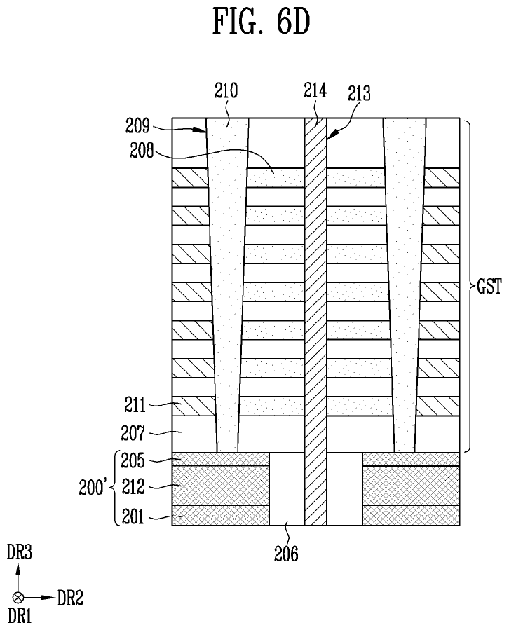

FIGS. 6A to 6D are views illustrating a method of manufacturing a memory device in accordance with an embodiment of the present disclosure.

Hereinafter, a method of manufacturing the memory device in accordance with the embodiment of the present disclosure will be described based on the contact region 112 of the gate stack structure GST described with reference to FIGS. 4A, 4B, 5A, and 5B. Hereinafter, for convenience of description, illustration of a peripheral circuit (PC shown in FIGS. 5A and 5B) is omitted.

Referring to FIG. 6A, a lower source structure 201, an interlayer sacrificial layer 203, and an upper source structure 205 may be sequentially stacked over a substrate (e.g., SUB shown in FIGS. 5A and 5B) or a sacrificial substrate (not shown), including a peripheral circuit (e.g., PC shown in FIGS. 5A and 5B), thereby forming a preliminary source structure 200. The preliminary source structure 200 may further include at least one of a first protective layer 202 disposed between the lower source structure 201 and the interlayer sacrificial layer 203 and a second protective layer 204 disposed between the interlayer sacrificial layer 203 and the upper source structure 205. The preliminary source structure 200 may include a top surface extending in the first direction DR1 and the second direction DR2, which intersect each other.

Subsequently, an insulating pattern 206 extending in the third direction DR3 intersecting the top surface of the preliminary source structure 200 may be formed in the preliminary source structure 200. The insulating pattern 206 may be formed in the same layout as the insulating pattern IP shown in FIG. 4A. That is, like the insulating pattern IP described with reference to FIG. 4A, the insulating pattern 206 may include a first part and a second part, which are alternately disposed in the first direction DR1 and are connected to each other, and the first part may be formed with a width wider than a width of the second part in the second direction DR2. For convenience of description, FIGS. 6A to 6D representatively illustrate a section of the first part of the insulating pattern 206.

After that, a plurality of first material layers 207 and a plurality of second material layers 208 may be alternately stacked over the top of the insulating pattern 206 and the preliminary source structure 200, thereby forming a preliminary gate stack structure PGST. For example, after a first material layer 207 is stacked on the insulating pattern 206 and the preliminary source structure 200, a second material layer 208 may be stacked on the first material layer 207. The plurality of second material layers 208 may have an etch selectivity with respect to the plurality of first material layers 207. For example, in a subsequent selective etching process, an etch selectivity of the plurality of first material layers 207 with respect to the plurality of second material layers 208 may be greater than 1. In an embodiment, the first material layer 207 may include an oxide such as a silicon oxide layer, and the second material layer 208 may include a nitride such as a silicon nitride layer.

Referring to FIG. 6B, a plurality of support holes 209 may be formed, which penetrate the preliminary gate stack structure PGST. Some of the plurality of first material layers 207 and the plurality of second material layers 208 of the preliminary gate stack structure PGST may be etched to form the plurality of support holes 209. The preliminary source structure 200 may be exposed through bottoms of the plurality of support holes 209. A layout of the plurality of support holes 209 may be designed corresponding to the layout of the plurality of support structures SS shown in FIGS. 4A and 4B.

A support structure 210 may be formed inside each of the plurality of support holes 209. The support structure 210 may include a material having an etch selectivity with respect to the plurality of second material layers 208 not to be removed in a subsequent selective etching process on the plurality of second material layers 208. In an embodiment, the support structure 210 may include an oxide. For example, the support structure 210 may include silicon oxide. The support structure 210 may overlap with the preliminary source structure 200.

Although not shown in the drawing, a process of forming the plurality of channel plugs CPL shown in FIGS. 4A and 4B may be performed separately from the process of forming the plurality of support holes 209 and the support structure 210. In an embodiment, the process of forming the plurality of channel plugs CPL shown in FIGS. 4A and 4B may include a process of forming a plurality of holes, a process of sequentially forming a blocking insulating layer, a data storage layer, and a tunnel insulating layer along a surface of each hole, and a process of forming a channel layer on the tunnel insulating layer. The plurality of holes may penetrate a partial area of the preliminary gate stack structure PGST, which corresponds to the cell array area 111 of the gate stack structure GST shown in FIG. 4B, and extend to the inside of a partial area of the preliminary source structure 200 corresponding to the cell overlapping source structure CSC shown in FIG. 4B. For example, the plurality of holes may extend to the inside of the lower source structure 201 of the preliminary source structure 200.

Referring to FIG. 6C, some of the plurality of second material layers 208 of the preliminary gate stack structure PGST shown in FIG. 6B may be replaced with a plurality of third material layers 211. In an embodiment, the process of replacing the plurality of second material layers 208 with the plurality of third material layers 211 may include a process of forming a slit (SLT shown in FIG. 4B) to penetrate the plurality of first material layers 207 and the plurality of second material layers 208, which are shown in FIG. 6B, a process of selectively etching some of the plurality of second material layers 208 shown in FIG. 6B through the slit (SLT shown in FIG. 4B), and a process of filling regions in which the plurality of second material layers 208 are etched with the plurality of third material layers 208 through the slit (SLT shown in FIG. 4B). Each third material layer 211 may include a conductive material. A portion of each of the second material layers 208 may be protected by the support structure 210 not to be replaced with the third material layer 211 but to remain like the sacrificial layer SCL described with reference to FIGS. 4A and 4B. Accordingly, the same gate stack structure GST as described with reference to FIGS. 4A, 4B, 5A, and 5B.

The interlayer sacrificial layer 203 of the preliminary source structure 200 shown in FIG. 6B may be replaced with an interlayer source structure 212. In an embodiment, the process of replacing the interlayer sacrificial layer 203 shown in FIG. 6B with the interlayer source structure 212 may include a process of forming a slit (SLT shown in FIG. 4A) such that the interlayer sacrificial layer 203 shown in FIG. 6B is exposed, a process of removing the interlayer sacrificial layer 203 shown in FIG. 6B through the slit (SLT shown in FIG. 4A), and a process of filling a region in which the interlayer sacrificial layer 203 is removed with the interlayer source structure 212 through the slit (SLT shown in FIG. 4A). The interlayer source structure 212 may include the same material as the lower source structure 201 and the upper source structure 205. Accordingly, a source structure 200′ may be formed. The slit (SLT shown in FIG. 4A) used as a path for replacing the interlayer sacrificial layer 203 shown in FIG. 6B with the interlayer source structure 212 penetrates the upper source structure 205, and may be disposed on the lower source structure 201. Although not shown in the drawing, before the interlayer source structure 212 is formed, a sidewall of a channel layer of a channel plug may be exposed by removing a portion of a memory layer of the channel plug through the region in which the interlayer sacrificial layer 203 shown in FIG. 6B is removed. In the process of removing a portion of the memory layer, the first protective layer 202 and the second protective layer 204, which are shown in FIG. 6B, may be removed, a bottom surface of the upper source structure 205 and a top surface of the lower source structure 201 may be exposed. The interlayer source structure 212 may be formed to be in contact with the exposed sidewall of the channel layer (not shown), the exposed bottom surface of the upper source structure 205, and the exposed top surface of the lower source structure 201.

Referring to FIG. 6D, a contact hole 213 may be formed, which penetrates the plurality of first material layers 207 and the plurality of second material layers 208 of the gate stack structure GST and extends to penetrate the insulating pattern 206. After that, the contact hole 213 may be filled with a conductive material, thereby forming a contact plug 214. In an embodiment, the contact plug 214 may include a metal such as tungsten (W). The contact plug 214 may be connected to the peripheral circuit PC shown in FIG. 4A.

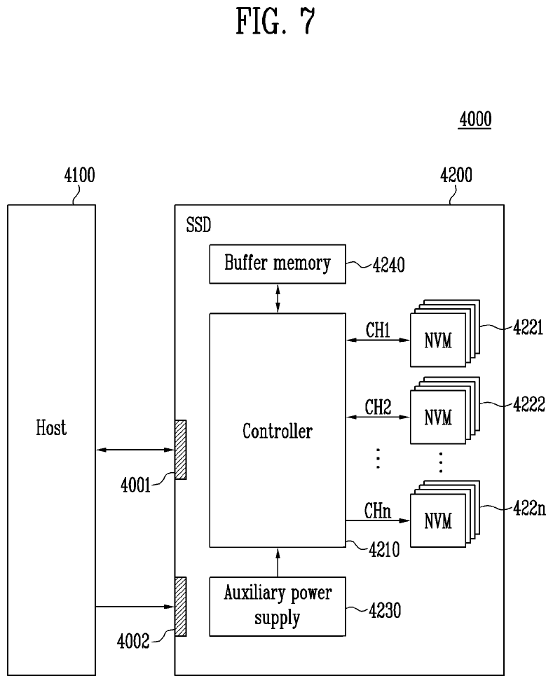

FIG. 7 is a diagram illustrating a Solid-State Drive (SSD) system to which the memory device of the present disclosure is applied.

Referring to FIG. 7, a SSD system 4000 includes a host 4100 and an SSD 4200. The SSD 4200 may exchange a signal with the host 4100 through a signal connector 4001, and be supplied with power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be transmitted based on an interface between the host 4100 and the SSD 4200. For example, the signal may be defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. Each of the plurality of memory devices 4221 to 422n may include a source structure and a contact plug spaced apart from the source structure, and the source structure of each of the plurality of memory devices 4221 to 422n may include a part concave while facing the contact plug. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power to the SSD 4200. Exemplarily, the auxiliary power supply 4230 may be located in the SSD 4200, or be located at the outside of the SSD 4200. For example, the auxiliary power supply 4230 may be located on a main board and provide auxiliary power to the SSD 4200.

The buffer memory 4240 may be used as a buffer memory of the SSD 4200. For example, the buffer memory 4240 may temporarily store data received from the host 4100 or data received from the plurality of memory devices 4221 to 422n, or temporarily store meta data (e.g., a mapping table) of the plurality of memory devices 4221 to 422n. The buffer memory 4240 may include volatile memory such as DRAM, SDRAM, DDR SDRAM, LPDDR SDRAM, and GRAM or nonvolatile memory such as FRAM, ReRAM, STT-MRAM, and PRAM.

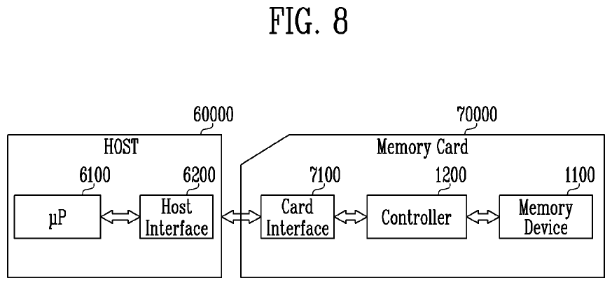

FIG. 8 is a diagram illustrating a memory card system to which the memory device of the present disclosure is applied.

Referring to FIG. 8, a memory system 70000 may be implemented as a memory card or a smart card. The memory system 70000 may include a memory device 1100, a controller 1200, and a card interface 7100.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor (μP) 6100.

The memory device 1100 may include a source structure and a contact plug spaced apart from the source structure, and the source structure of the memory device 1100 may include a part concave while facing the contact plug.

In accordance with the present disclosure, a process defect of a memory device may be reduced.

What is claimed is:

1. A memory device comprising:
a source structure including a top surface extending along a first direction and a second direction, which intersect each other, the source structure including a concave part and a protrusion part, which are alternately disposed along the first direction;
a contact plug spaced apart from a sidewall of the source structure, the contact plug facing the concave part; and
a gate stack structure including a plurality of insulating layers and a plurality of conductive layers, which are alternately disposed over the source structure,
wherein the protrusion part of the source structure protrudes farther in the second direction than the concave part of the source structure.

2. The memory device of claim 1, further comprising a first support structure disposed over the source structure, the first support structure having a first support part corresponding to the concave part of the source structure and a second support part corresponding to the protrusion part of the source structure,
wherein the second support part of the first support structure has a width wider than a width of the first support part of the first support structure in the second direction.

3. The memory device of claim 2, further comprising:
a second support structure facing the first support part of the first support structure; and
a gate contact facing the second support part of the first support structure, the gate contact being in contact with one conductive layer among the plurality of conductive layers.

4. The memory device of claim 3, wherein the first support structure and the second support structure include an insulating material.

5. The memory device of claim 1, wherein the source structure includes a first source structure and a second source structure, and
wherein the first source structure and the second source structure are spaced apart from each other with the contact plug interposed therebetween.

6. The memory device of claim 5, wherein an insulating pattern surrounding the contact plug is disposed between the first source structure and the second source structure.

7. The memory device of claim 6, wherein the insulating pattern has:
a first width between a concave part of the first source structure and a concave part of the second source structure; and
a second width between a protrusion part of the first source structure and a protrusion part of the second source structure, and
wherein the first width is wider than the second width.

8. The memory device of claim 1, further comprising a peripheral circuit disposed under the source structure, the peripheral circuit being electrically connected to the contact plug.

9. A memory device comprising:
an insulating pattern including a first part and a second part, which are alternately disposed in a first direction and are connected to each other, wherein the first part is formed with a width wider than a width of the second part in a second direction intersecting the first direction;
a source structure in contact with sidewalls of the insulating pattern and extending away from the sidewalls of the insulating pattern in the second direction and in a direction opposite to the second direction, wherein the sidewalls of the insulating pattern are adjacent to each other in the second direction;
a contact plug penetrating the first part of the insulating pattern; and
a gate stack structure disposed over the source structure.

10. The memory device of claim 9, further comprising a peripheral circuit disposed under the source structure,
wherein the contact plug is electrically connected to the peripheral circuit.

11. The memory device of claim 9, wherein a sidewall of the source structure includes a concave part in contact with the first part of the insulating pattern and a protrusion part in contact with the second part of the insulating pattern, and
wherein the protrusion part protrudes farther toward the insulating pattern than the concave part.

12. The memory device of claim 9, further comprising a support structure penetrating the gate stack structure,
wherein the support structure has a concave part and a protrusion part, which are alternately disposed in the first direction.

13. The memory device of claim 12, wherein the concave part of the support structure corresponds to the first part of the insulating pattern, and
the protrusion part of the support structure corresponds to the second part of the insulating pattern.

14. The memory device of claim 12, wherein the support structure includes an insulating material.
